(19) United States
(12) Patent Application Publication
(10) Pub. No.: US 2026/0100333 A1
(43) Pub. Date: Apr. 9, 2026

(54) MICROWAVE PLASMA SOURCE WITH NON-CYLINDRICAL CAVITY ANTENNAS

(71) Applicant: Applied Materials, Inc., Santa Clara, CA (US)

(72) Inventors: SATHYA SWAROOP GANTA, Sunnyvale, CA (US); KALLOL BERA, San Jose, CA (US); JOSEPH AUBUCHON, San Jose, CA (US)

(21) Appl. No.: 18/908,421

(22) Filed: Oct. 7, 2024

(51) Int. Cl. H01J 37/32

(52) U.S. Cl. CPC H01J 37/3222

(57) ABSTRACT

Embodiments described herein relate to an apparatus that includes a plate, where the plate includes a first dielectric material, and a resonator coupled to the plate. In an embodiment, the resonator includes a second dielectric material, and the resonator has a cross-sectional shape with a first end with a first width and a second end with a second width that is smaller than the first width. In an embodiment, the first end faces the plate.

### BACKGROUND

### 1) Field

Embodiments relate to the field of semiconductor manufacturing and, in particular, microwave plasma sources with a plurality of non-cylindrical dielectric resonator antennas.

### 2) Description of Related Art

Microwave plasma sources provide different distributions of species than lower frequency plasma sources (e.g., RF plasma sources) that are typically used in semiconductor processing operations, such as deposition processes, etching process, plasma treatment processes, or the like. For example, microwave plasma sources typically provide higher density plasmas with lower energy distribution functions. However, existing microwave plasma source designs are limited in their ability to provide good plasma uniformity. One proposed solution to improve plasma uniformity is to provide a pixelated plasma source. In a pixelated plasma source, a plurality of microwave dielectric resonators are used to provide multiple microwave injection points to the chamber.

However, the size of the dielectric resonators is constrained by the resonance characteristics dictated by the dielectric constant of the material used for the dielectric resonator. The limited size options for the dielectric resonators may result in the need for many dielectric resonators in order to provide a uniform plasma. Since each of the dielectric resonators have their own microwave amplifier and corresponding cabling, the cost of such systems can grow rapidly. Additionally, even though the dielectric resonators are independently controllable, the plasma uniformity may still be difficult to optimize due to the overlap of microwave power emitted from neighboring dielectric resonators.

### SUMMARY

Embodiments described herein relate to an apparatus that includes a plate, where the plate includes a first dielectric material, and a resonator coupled to the plate. In an embodiment, the resonator includes a second dielectric material, and the resonator has a cross-sectional shape with a first end with a first width and a second end with a second width that is smaller than the first width. In an embodiment, the first end faces the plate.

Embodiments described herein relate to an apparatus that includes a plate, where the plate includes a first dielectric material, and a resonator coupled to the plate. In an embodiment, the resonator includes a second dielectric material. In an embodiment, the resonator includes a first circular portion, and a second circular portion that intersects the first circular portion.

Embodiments described herein relate to an apparatus that includes a plate, where the plate includes a first dielectric material, and a resonator coupled to the plate. In an embodiment, the resonator includes a second dielectric material. In an embodiment, the resonator includes a first layer on the plate, with a first dielectric cavity and a second dielectric cavity adjacent to the second dielectric cavity. In an embodiment, the resonator includes a second layer on the first layer, where the second layer includes a third dielectric cavity that overlaps at least a portion of the first dielectric cavity and at least a portion of the second dielectric cavity.

### BRIEF DESCRIPTION OF THE DRAWINGS

FIG. 1A is a cross-sectional illustration of a portion of a microwave plasma source that illustrates a single dielectric resonator coupled to a microwave power amplifier, in accordance with an embodiment.

FIG. 1B is a plan view illustration of a microwave plasma source that comprises a plurality of dielectric resonators distributed across a dielectric plate, in accordance with an embodiment.

FIG. 1C is a cross-sectional illustration of the microwave plasma source in FIG. 1B that illustrates a relatively high degree of plasma flux non-uniformity, in accordance with an embodiment.

FIG. 2A is a cross-sectional illustration of a portion of a microwave plasma source that depicts a single dielectric resonator with a sloped sidewall, in accordance with an embodiment.

FIG. 2B is a plan view illustration of a microwave plasma source that comprises a plurality of dielectric resonators with sloped sidewalls, in accordance with an embodiment.

FIG. 2C is a cross-sectional illustration of the microwave plasma source in FIG. 2B that illustrates an improved plasma flux uniformity compared to the embodiment shown in FIG. 1C, in accordance with an embodiment.

FIG. 3A is a cross-sectional illustration of a portion of a microwave plasma source that depicts a single dielectric resonator with overlapping circular portions, in accordance with an embodiment.

FIG. 3B is a plan view illustration of a portion of a microwave plasma source that depicts a single dielectric resonator with overlapping circular portions, in accordance with an embodiment.

FIG. 3C is a plan view illustration of a portion of a microwave plasma source that depicts a single dielectric resonator with a set of three overlapping circular portions, in accordance with an embodiment.

FIG. 3D is a plan view illustration of a portion of a microwave plasma source that depicts a single dielectric resonator with a set of four overlapping circular portions, in accordance with an embodiment.

FIG. 4A is a cross-sectional illustration of a portion of a microwave plasma source that depicts a single dielectric resonator with a multi-layer construction, where a first layer comprises a pair of dielectric cavities, and a second layer comprises a dielectric cavity that overlaps a portion of the dielectric cavities in the first layer, in accordance with an embodiment.

FIG. 4B is a plan view illustration of a portion of a microwave plasma source that depicts a single dielectric resonator with a multi-layer construction, where a first layer comprises a pair of dielectric cavities, and a second layer comprises a dielectric cavity that overlaps a portion of the dielectric cavities in the first layer, in accordance with an embodiment.

FIG. 4C is a plan view illustration of a portion of a microwave plasma source that depicts a single dielectric resonator with a multi-layer construction, where a first layer comprises three dielectric cavities, and a second layer comprises a dielectric cavity that overlaps a portion of the dielectric cavities in the first layer, in accordance with an embodiment.

FIG. 4D is a plan view illustration of a portion of a microwave plasma source that depicts a single dielectric resonator with a multi-layer construction, where a first layer comprises four dielectric cavities, and a second layer comprises a dielectric cavity that overlaps a portion of the dielectric cavities in the first layer, in accordance with an embodiment.

FIG. 5 is a cross-sectional illustration of a processing tool that comprises a microwave plasma source with a plurality of dielectric resonators with sloped sidewalls arranged over a dielectric plate, in accordance with an embodiment.

FIG. 6 illustrates a block diagram of an exemplary computer system that may be used in conjunction with a processing tool, in accordance with an embodiment.

### DETAILED DESCRIPTION

Embodiments described herein include microwave power sources with a plurality of non-cylindrical dielectric resonator antennas. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, microwave plasma sources may suffer from poor plasma uniformity. That is, the flux of species from plasma that are delivered to an underlying substrate may not be consistent across a surface of the substrate. Such non-uniformity is detrimental to processing operations (e.g., etching, deposition, treatment, etc.) since the processed substrate will not have a uniform surface (e.g., with respect to film thickness, feature profile, chemical composition, etc.). This can lead to defective devices on the substrate and reduce product yield. Accordingly, the benefits of microwave plasmas, such as high plasma densities and low energy distribution functions cannot be fully utilized.

One solution for improving microwave plasma uniformity is to use a pixelated (or modular) microwave plasma approach. In such an embodiment, a plurality of dielectric resonators (which may also be referred to as microwave antennas or applicators) are distributed across a surface of a dielectric plate. The plurality of dielectric resonators are each coupled to their own microwave power amplifier and can be independently controlled. The layout pattern of the dielectric resonators may also be a symmetric pattern in order to improve plasma uniformity. For example, the pattern may sometimes be radially symmetric. In order to provide a desired plasma uniformity, a large number of dielectric resonators may be used. For example, ten or more dielectric resonators or fifteen or more dielectric resonators may be used in high volume manufacturing (HVM) semiconductor processing tools. This increases the overall cost and complexity of such tools.

Additionally, the use of a modular microwave plasma source still does not provide the desired plasma uniformity in some applications. This is because each dielectric resonator provides a flux distribution that spreads wider than the diameter of the dielectric resonator. As such, the flux from neighboring dielectric resonators will add to each other, and it is difficult to provide a net plasma flux uniformity across the entire width of the plasma. In order to reach acceptable plasma flux uniformities, precise control of processing conditions and/or hardware configurations are needed. This may reduce flexibility of the processing tool to operate over large process windows, and the capabilities of the processing tool may be limited.

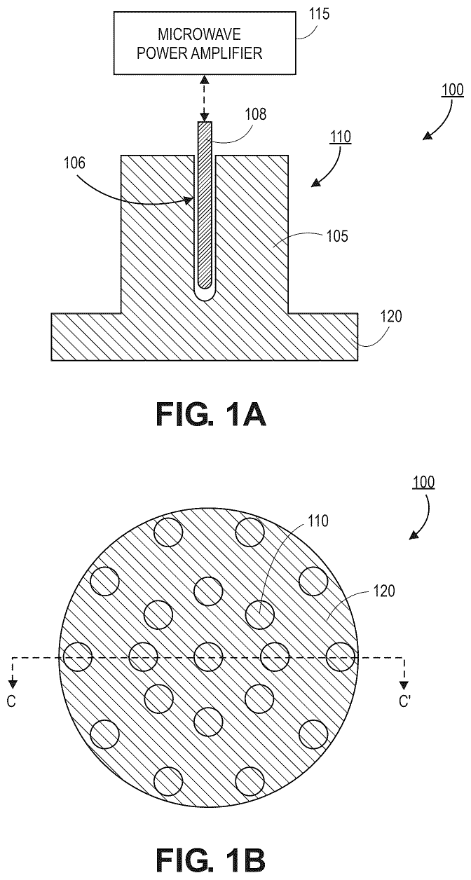

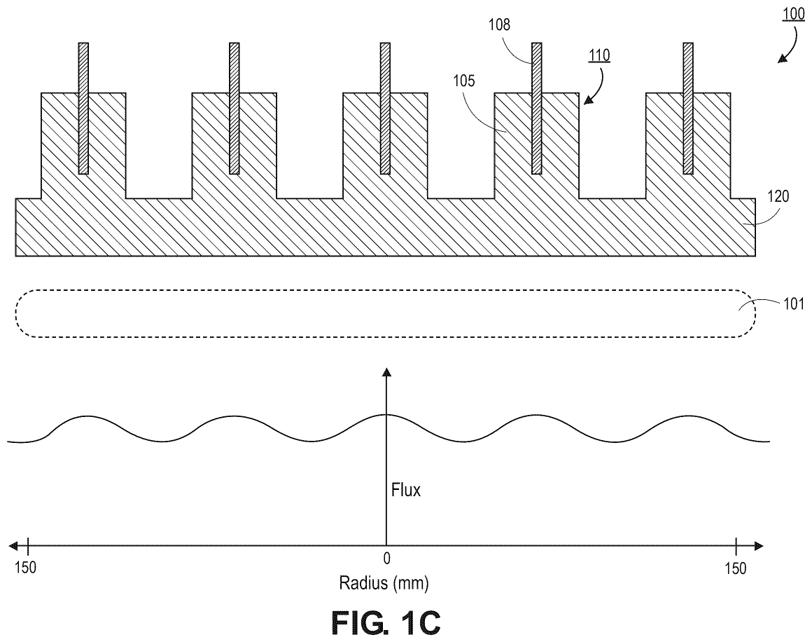

Referring now to FIG. 1A, a cross-sectional illustration of a portion of such a microwave plasma source 100 is shown, in accordance with an embodiment. In an embodiment, the microwave plasma source 100 may comprise a dielectric plate 120 and a dielectric resonator 110 coupled to the dielectric plate 120. In the illustrated embodiment, the dielectric resonator 110 and the dielectric plate 120 are a monolithic structure. Though, in other embodiments, the dielectric plate 120 and the dielectric resonator 110 may comprise discrete components. In an embodiment, the dielectric resonator 110 and the dielectric plate 120 may comprise any suitable dielectric material. For example, the dielectric resonator 110 and the dielectric plate 120 may comprise alumina or the like.

In an embodiment, the dielectric resonator 110 may comprise a dielectric puck 105. The dielectric puck 105 may be sized in order to provide a resonant cavity based on the frequency of the microwave power and the dielectric constant of the dielectric puck 105. In some embodiments, the dielectric puck 105 is cylindrical. While not shown, an electrically conductive housing or shielding may be provided along sidewalls of the dielectric puck 105.

In an embodiment, the dielectric resonator 110 may also comprise a hole 106 that passes into the dielectric puck 105. An electrically conductive pin 108 may be inserted into the hole 106. While the hole 106 and pin 108 are shown as being at an axial center of the dielectric puck 105, it is to be appreciated that the hole 106 and the pin 108 may be located at any location within the dielectric puck 105 and/or oriented at any angle relative to the dielectric plate. Further, any suitable hole 106 depth, hole 106 shape, pin 108 shape, and/or the like may be used for the dielectric resonator 110.

In an embodiment, the pin 108 may be electrically coupled to a microwave power amplifier 115. The electrical coupling between the pin 108 and the microwave power amplifier 115 may include any number of components, cables, and/or the like. For example, an impedance match, a coaxial cable, circuitry, and/or the like may be provided along an electrical path between the pin 108 and the microwave power amplifier 115.

In an embodiment, microwave power from the microwave power amplifier is propagated to the pin 108. The resonant cavity of the dielectric puck 105 allows for the microwave power to be coupled into the dielectric material and propagate into the dielectric plate 120. The bottom surface of the dielectric plate 120 may be within a vacuum chamber that can support a plasma that is ignited and sustained by the microwave power.

Referring now to FIG. 1B, a plan view illustration of a microwave plasma source 100 is shown, in accordance with an embodiment. The microwave plasma source 100 may comprise a dielectric plate 120 with a plurality of dielectric resonators 110 distributed across the dielectric plate 120. The dielectric resonators 110 in FIG. 1B may each be similar to the dielectric resonator 110 in FIG. 1A. For example, the dielectric resonators 110 may each comprise a conductive pin that is inserted into a hole of the dielectric resonator 110. In an embodiment, each of the dielectric resonators 110 may be electrically coupled to different microwave power amplifiers (not shown). As such, the dielectric resonators 110 may be independently controlled.

In an embodiment, the dielectric resonators 110 may be arranged across the dielectric plate 120 in a pattern that includes concentric rings of dielectric resonators 110 around a center-point (or origin) of the dielectric plate 120. For example, the pattern may be radially symmetric. In FIG. 1B, there are nineteen dielectric resonators 110. Though, embodiments may include any number of dielectric resonators 110 in the microwave plasma source 100.

As noted above, such a construction for the microwave plasma source 100 may still suffer from plasma non-uniformities even though a radially symmetric pattern is used for the layout of the dielectric resonators 110. This may be due, at least in part, to the distribution of microwave power that is emitted from each of the dielectric resonators 110. For example, the distribution for each dielectric resonator 110 may have a peak at an axial center of the dielectric resonator 110, with tail ends that extend out past a width of the dielectric resonator 110. The tail ends of the distribution may overlap the microwave power of one or more of the other dielectric resonators 110. As such, it may be difficult to provide a uniform level of microwave power across the dielectric plate 120 due to the microwave power added by each dielectric resonator 110. Even with individual control of the dielectric resonators 110, a desired level of uniformity may not be obtainable. Even when acceptable uniformity is provided, the process window may be small. As such, the capability of the processing tool coupled to the microwave plasma source 100 is not fully realized.

Referring now to FIG. 1C, a cross-sectional illustration of the microwave plasma source 100 in FIG. 1B along line C-C′ is shown, in accordance with an embodiment. As shown, the microwave power emitted by the dielectric resonators 110 and spread through the dielectric plate 120 can be used to ignite and/or sustain a plasma 101. The microwave plasma source 100 may be coupled to a chamber (not shown) and the plasma 101 may be formed within the chamber. As described above, the microwave power distribution emitted by the microwave plasma source 100 may be non-uniform. This can lead to a plasma 101 that has a non-uniform plasma flux towards a substrate (not shown) that is provided below the dielectric plate 120.

In FIG. 1C, the graph below the plasma 101 illustrates the non-uniform plasma flux over a width of a substrate (not shown). As shown, the plasma flux may peak below center-points of the dielectric resonators 110 and have valleys between the dielectric resonators 110. This wave-like pattern can lead to unacceptable process non-uniformities on the substrate. For example, a degree of uniformity of the plasma 101 may be approximately 90% or less, approximately 80% or less, or approximately 75% or less. As used herein, the degree of uniformity α may be described by Equation 1, where nₘₐₓ is the peak of the flux distribution across the substrate, nₘᵢₙ is the minimum of the flux distribution across the substrate, and nₐᵥₑ is the average of the flux distribution across the substrate.

$$α = ( 1 - \frac{{n}_{m ax} - {n}_{m i n}}{2 {n}_{a v e}} ) \times 100 \% \qquad Equation 1$$

Accordingly, embodiments disclosed herein aim to improve the degree of uniformity of the plasma flux across the underlying substrate. One approach to improve the degree of uniformity is to provide dielectric resonators with a wider plasma flux distribution below the dielectric resonator. However, the width of the dielectric resonator cannot be arbitrarily increased due to the resonance characteristics of the dielectric resonator for a given frequency of operation. For example, the resonance of the dielectric resonator may be based on dielectric constants and/or the geometry of the dielectric resonator. As such, arbitrarily increasing the diameter of the dielectric resonator does not allow the plasma flux distribution to be widened.

As such, embodiments disclosed herein include dielectric resonator architectures that are able to sustain resonance while spreading the plasma flux distribution to a larger area. For example, a total area of the dielectric resonator that is in contact with the underlying dielectric plate is larger than the area of a single cylindrical resonator made from the same dielectric material. That is, the dielectric resonators disclosed herein may include the fusion of multiple resonant cavities into a single structure. In one embodiment, the dielectric resonator is formed with sloped sidewalls in order to retain an upper end of the dielectric resonator at a dimension that supports resonance, while a lower end is wider to spread the plasma flux distribution. Such a dielectric resonator may sometimes be referred to as a conical or frustoconical dielectric resonator.

In another embodiment, the dielectric resonator may comprise a plurality of circular portions that at least partially intersect each other. In such an embodiment, the hole and pin may be inserted into the intersecting portion of the circular portions. This allows the microwave power to resonate in all of the circular portions at the same time. As such, the total area of the dielectric resonator can be increased in order to allow for improved spreading of the plasma flux distribution.

In yet another embodiment, the dielectric resonator may comprise a multi-layer approach. In such an embodiment, the first layer may comprise a plurality of dielectric cavities that are spaced apart from each other. The second layer may comprise an additional dielectric cavity that overlaps at least a portion of each of the dielectric cavities in the first layer. The hole and pin may be inserted into the dielectric cavity in the second layer. The microwave power can resonate within the dielectric cavity of the second layer and couples into the dielectric cavities of the first layer where resonance is also obtained. As such, a single input can provide a wider area plasma flux distribution by spreading the microwave power into a plurality of dielectric cavities in the first layer.

In addition to providing improved plasma flux uniformity, embodiments disclosed herein also simplify the design, construction, and/or control of the microwave plasma source. For example, the wider plasma flux distribution from each dielectric resonator allows for fewer microwave power channels to be used in the microwave plasma source. As such, fewer microwave amplifiers, generators, impedance matches, dielectric resonators, and/or the like are needed, and a cost of the system may be reduced.

Additionally, fewer microwave power channels simplify the control of the microwave plasma system. Reducing the number of dielectric resonators reduces the amount of cross-talk within the system. This can lead to a system that is easier to tune over a large process window. Accordingly, embodiments may allow for microwave processing tools that are able to implement multiple different processing recipes, or to implement processing recipes with various process conditions. Such flexibility may increase a value of a tool within an HVM semiconductor processing environment.

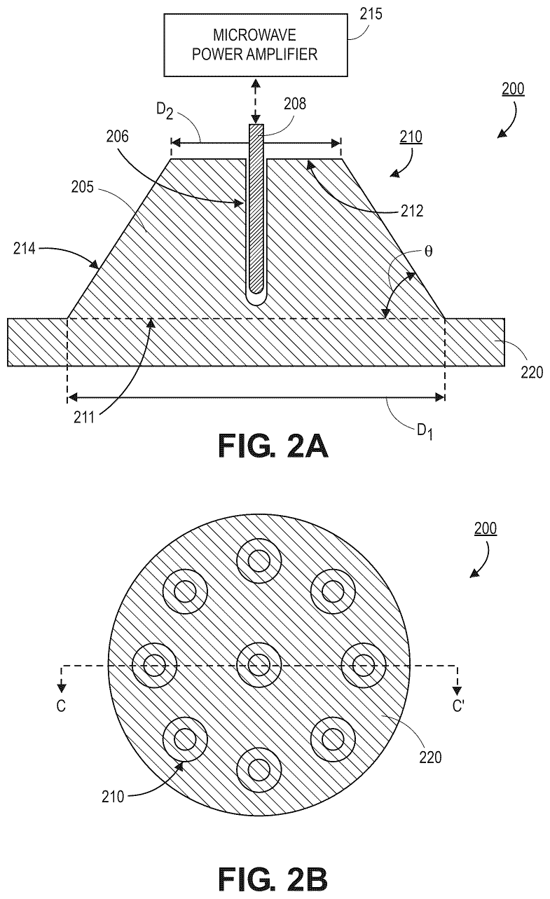

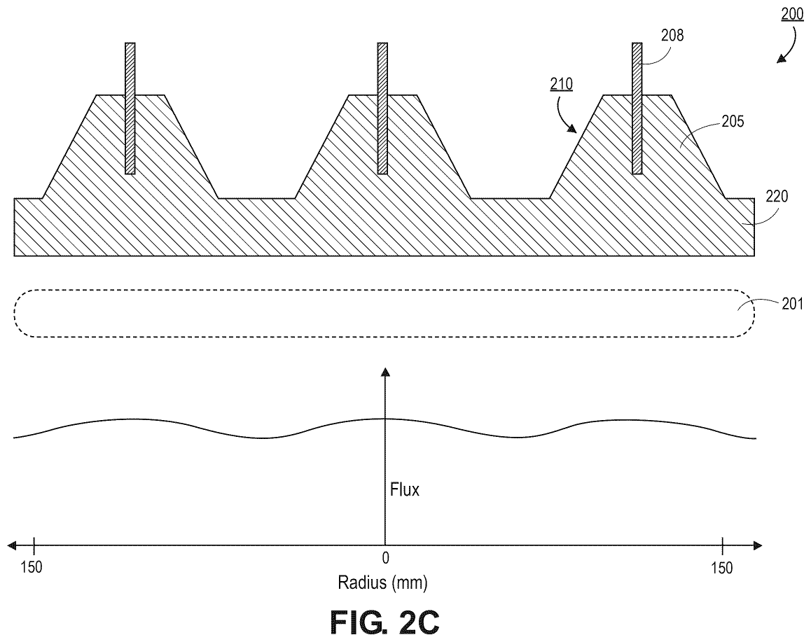

Referring now to Figure FIGS. 2A-2C, a series of illustrations depicting a microwave plasma source 200 with dielectric resonators 210 with sloped sidewalls to enable plasma flux distribution spreading is shown, in accordance with an embodiment.

Referring now to FIG. 2A, a cross-sectional illustration of a portion of a microwave plasma source 200 is shown, in accordance with an embodiment. In an embodiment, the microwave plasma source 200 may comprise a dielectric plate 220 and a dielectric resonator 210 coupled to the dielectric plate 220. In the illustrated embodiment, the dielectric resonator 210 and the dielectric plate 220 are a monolithic structure. Though, in other embodiments, the dielectric plate 220 and the dielectric resonator 210 may comprise discrete components. In an embodiment, the dielectric resonator 210 and the dielectric plate 220 may comprise any suitable dielectric material. For example, the dielectric resonator 210 and the dielectric plate 220 may comprise alumina or the like.

In an embodiment, the dielectric resonator 210 may comprise a dielectric puck 205. The dielectric puck 205 may be sized in order to provide a resonant cavity based on the frequency of the microwave power and the dielectric constant of the dielectric puck 205. While not shown, an electrically conductive housing or shielding may be provided along sidewalls of the dielectric puck 205. In a particular embodiment, the dielectric puck 205 may comprise a sloped sidewall 214. For example, the sidewall 214 may be sloped at an angle θ that is between approximately 30° and approximately 60°. In some embodiments, the angle θ may be approximately 45°.

The sloped sidewall 214 allows for a first end 211 of the dielectric resonator 210 to have a larger first diameter D₁ (or width) than a second diameter D₂ (or width) of a second end 212 of the dielectric resonator 210. In some embodiments, the second diameter D₂ may be up to approximately 90% of the first diameter D₁, up to approximately 80% of the first diameter D₁, up to approximately 75% of the first diameter D₁, or up to approximately 50% of the first diameter D₁. In an embodiment, the geometry of the dielectric puck 205 may be chosen in order to support resonance of the microwave power at a given frequency. By increasing the first diameter D₁, the plasma flux distribution can be spread compared to a cylindrical dielectric puck that may have a uniform second diameter D₂. In some embodiments, the shape of the dielectric puck 205 may sometimes be referred to as being conical or as being frustoconical.

In an embodiment, the dielectric resonator 210 may also comprise a hole 206 that passes into the dielectric puck 205 through the second end 212 of the dielectric puck 205. An electrically conductive pin 208 may be inserted into the hole 206. While the hole 206 and pin 208 are shown as being at an axial center of the dielectric puck 205, it is to be appreciated that the hole 206 and the pin 208 may be located at any location within the dielectric puck 205 and/or oriented at any angle relative to the dielectric plate 220. Further, any suitable hole 206 depth, hole 206 shape, pin 208 shape, and/or the like may be used for the dielectric resonator 210.

In an embodiment, the pin 208 may be electrically coupled to a microwave power amplifier 215. The electrical coupling between the pin 208 and the microwave power amplifier 215 may include any number of components, cables, and/or the like. For example, an impedance match, a coaxial cable, circuitry, and/or the like may be provided along an electrical path between the pin 208 and the microwave power amplifier 215.

In an embodiment, microwave power from the microwave power amplifier is propagated to the pin 208. The resonant cavity of the dielectric puck 205 allows for the microwave power to be coupled into the dielectric material and propagate into the dielectric plate 220. The bottom surface of the dielectric plate 220 may be within a vacuum chamber that can support a plasma that is ignited and sustained by the microwave power.

Referring now to FIG. 2B, a plan view illustration of a microwave plasma source 200 is shown, in accordance with an embodiment. The microwave plasma source 200 may comprise a dielectric plate 220 with a plurality of dielectric resonators 210 distributed across the dielectric plate 220. The dielectric resonators 210 in FIG. 2B may each be similar to the dielectric resonator 210 in FIG. 2A. For example, the dielectric resonators 210 may each comprise a conductive pin (not shown) that is inserted into a hole (not shown) of the dielectric resonator 210. As shown, each dielectric resonator 210 has a first circle and a second larger circle to indicate the sloped sidewalls of the dielectric resonators 210. In an embodiment, each of the dielectric resonators 210 may be electrically coupled to different microwave power amplifiers (not shown). As such, the dielectric resonators 210 may be independently controlled.

In an embodiment, the dielectric resonators 210 may be arranged across the dielectric plate 220 in a pattern that includes a concentric ring of dielectric resonators 210 around a center-point (or origin) of the dielectric plate 220, and an additional dielectric resonator 210 may be provided at the center-point of the dielectric plate 220. In some embodiments, the pattern may be radially symmetric, asymmetric, or any other suitable pattern. In FIG. 2B, there are nine dielectric resonators 210. Though, embodiments may include any number of dielectric resonators 210 in the microwave plasma source 200.

More particularly, it is to be appreciated that a number of dielectric resonators 210 in FIG. 2B may be reduced compared to the number of dielectric resonators 110 shown in FIG. 1B due to the wider plasma flux distribution provided by the dielectric resonators 210. As such, the cost and/or complexity of the microwave plasma source 200 may be reduced.

Referring now to FIG. 2C, a cross-sectional illustration of the microwave plasma source 200 in FIG. 2B along line C-C′ is shown, in accordance with an embodiment. As shown, the microwave power emitted by the dielectric resonators 210 and spread through the dielectric plate 220 can be used to ignite and/or sustain a plasma 201. The microwave plasma source 200 may be coupled to a chamber (not shown) and the plasma 201 may be formed within the chamber. As described above, the microwave power distribution emitted by the microwave plasma source 200 may be more uniform than the microwave plasma source 100 described above.

In FIG. 2C, the graph below the plasma 201 illustrates the improved plasma flux uniformity over a width of a substrate (not shown). As shown, the plasma flux may peak below center-points of the dielectric resonators 210 and have valleys between the dielectric resonators 210. This wave-like pattern may have an improved degree of uniformity since fewer dielectric resonators are needed to span the width of the dielectric plate 220, and because the plasma flux distribution of each dielectric resonator is spread wider (so that peaks and valleys are reduced in magnitude). For example, a degree of uniformity of the plasma 201 may be approximately 90% or more, approximately 95% or more, or approximately 99% or more.

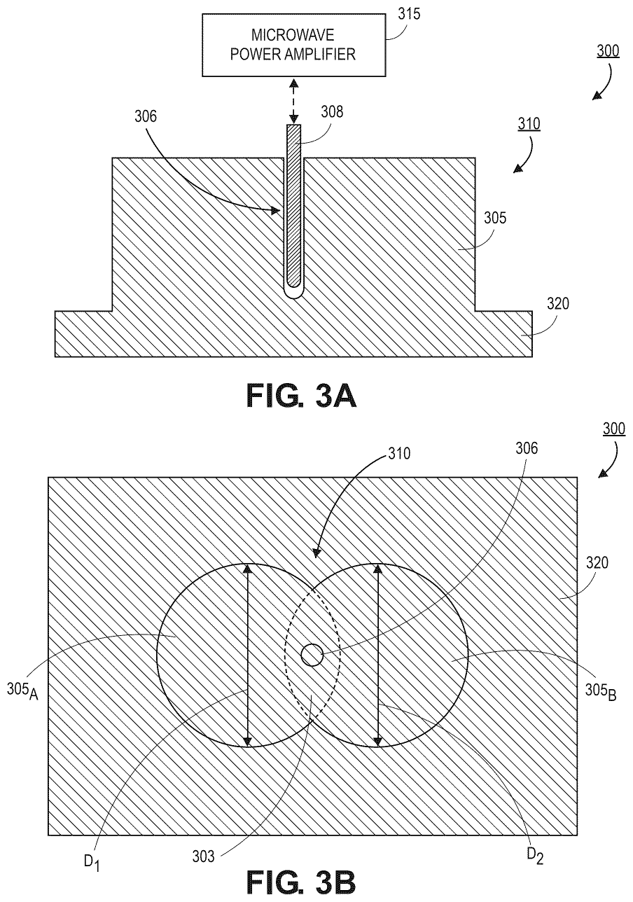

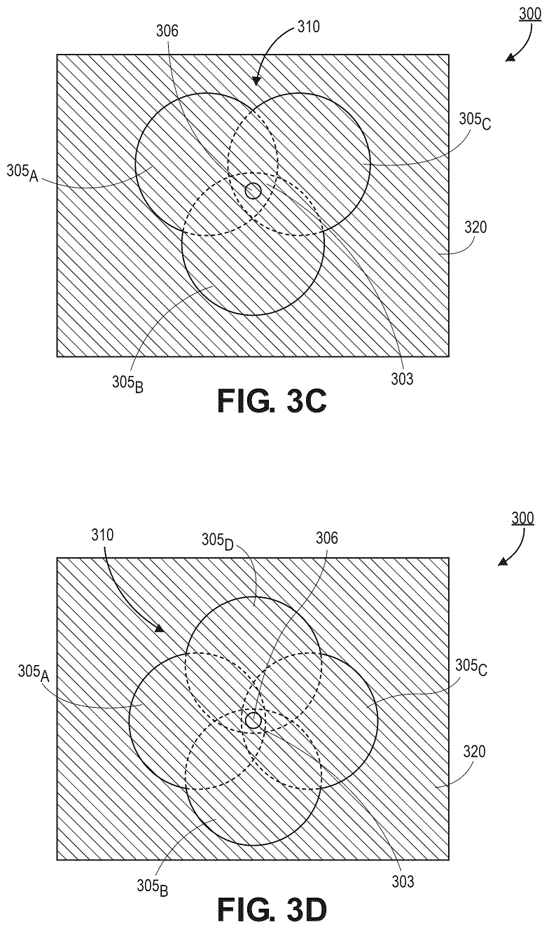

Referring now to FIGS. 3A-3D, a series of illustrations depicting a microwave plasma source 300 with dielectric resonators 310 with intersecting circular portions is shown, in accordance with various embodiments.

Referring now to FIG. 3A, a cross-sectional illustration of a portion of a microwave plasma source 300 is shown, in accordance with an embodiment. In an embodiment, the microwave plasma source 300 may comprise a dielectric plate 320 and a dielectric resonator 310 coupled to the dielectric plate 320. In the illustrated embodiment, the dielectric resonator 310 and the dielectric plate 320 are a monolithic structure. Though, in other embodiments, the dielectric plate 320 and the dielectric resonator 310 may comprise discrete components. In an embodiment, the dielectric resonator 310 and the dielectric plate 320 may comprise any suitable dielectric material. For example, the dielectric resonator 310 and the dielectric plate 320 may comprise alumina or the like.

In an embodiment, the dielectric resonator 310 may comprise a dielectric puck 305. The dielectric puck 305 may be sized in order to provide a resonant cavity based on the frequency of the microwave power and the dielectric constant of the dielectric puck 305. While not shown, an electrically conductive housing or shielding may be provided along sidewalls of the dielectric puck 305. In a particular embodiment, the dielectric puck 305 may include a plurality of intersecting circular portions. The circular portions are not visible in the cross-sectional view of FIG. 3A since the intersecting portions may be a monolithic structure. The circular portions are more clearly described in FIGS. 3B-3D below. The intersecting circular portions allow for a wider spread of the plasma flux distribution.

In an embodiment, the dielectric resonator 310 may also comprise a hole 306 that passes into the dielectric puck 305, and an electrically conductive pin 308 may be inserted into the hole 306. In an embodiment, the hole 306 and pin 308 may be similar in construction, geometry, and/or orientation to any of the holes and/or pins described in greater detail herein.

In an embodiment, the pin 308 may be electrically coupled to a microwave power amplifier 315. The microwave power amplifier 315 and any intervening components and/or coupling structures (e.g., waveguides, coaxial cables, etc.) may be similar to any of those described in greater detail herein.

In an embodiment, microwave power from the microwave power amplifier is propagated to the pin 308. The resonant cavity of the dielectric puck 305 allows for the microwave power to be coupled into the dielectric material and propagate into the dielectric plate 320. The bottom surface of the dielectric plate 320 may be within a vacuum chamber that can support a plasma that is ignited and sustained by the microwave power.

Referring now to FIG. 3B, a plan view illustration of a portion of the microwave plasma source 300 is shown, in accordance with an embodiment. As shown, the microwave plasma source 300 may comprise a dielectric plate 320 with a dielectric resonator 310 provided over the dielectric plate 320. The dielectric resonator 310 may be similar to the dielectric resonator 310 described in FIG. 3A. As shown, the dielectric resonator 310 may comprise a dielectric puck 305 with a first circular portion 305_{A} and a second circular portion 305_{B}. In an embodiment, the first circular portion 305_{A} may partially intersect a portion of the second circular portion 305_{B}. For example, an intersection region 303 may be provided within the dielectric resonator 310, as indicated by the dashed lines that show the continuing shape of each of the circular portions 305_{A} and 305_{B}.

However, it is to be appreciated that the dielectric resonator 310 may be a monolithic structure so that that the first circular portion 305_{A} and the second circular portion 305_{B} are combined as a single structure without a seam between them in some embodiments. Though, in other embodiments, the first circular portion 305_{A} may be a continuous cylinder, and the second circular portion 305_{B} may have a cutout to accommodate the first circular portion 305_{A} SO that the two circular portions directly contact each other with a seam between them.

As can be appreciated, a “circular portion” may refer to a portion of a cylinder that is visible as an edge of the dielectric resonator 310 and a portion of the dielectric resonator outlined by an imaginary curve that completes a circle when coupled to the visible edge of the dielectric resonator 310. For example, the first circular portion 305_{A} may be considered as being the left half of the dielectric resonator 310 and the intersection region 303, and the second circular portion 305_{B} may be considered as being the right half of the dielectric resonator 310 and the intersection region 303. The intersection region 303 may refer to a region of the dielectric resonator 310 that is bounded by imaginary lines that define the full circle for each of the first circular portion 305_{A} and the second circular portion 305_{B} (which are shown by the dashed lines in FIG. 3B).

In an embodiment, the hole 306 for the pin (not shown) may be positioned within the intersection region 303. In such an embodiment, the incoming microwave power may be coupled into both the first circular portion 305_{A} and the second circular portion 305_{B}. In this way, the microwave power is spread in order to provide a wider plasma flux distribution compared to the use of a single cylindrical dielectric puck.

As shown in FIG. 3B, the first circular portion 305_{A} may have a first diameter D₁ and the second circular portion 305_{B} may have a second diameter D₂. The first diameter D₁ and the second diameter D₂ may be the same in some embodiments. That is, the first circular portion 305_{A} and the second circular portion 305_{B} may have geometries that are the same, so that both can support the resonance of the incoming microwave power.

Referring now to FIG. 3C, a cross-sectional illustration of a portion of a microwave plasma source 300 is shown, in accordance with an additional embodiment. In an embodiment, the microwave plasma source 300 in FIG. 3C is similar to the microwave plasma source 300 in FIG. 3B, with the addition of a third circular portion 305_{C}. In an embodiment, the three circular portions 305_{A}, 305_{B}, and 305_{C} may all partially overlap each other to form an intersection region 303. The intersection region 303 may be defined by the imaginary dashed lines that continue the circular shapes of each of the circular portions 305_{A}, 305_{B}, and 305_{C}. Similar to the embodiment in FIG. 3B, the hole 306 for the pin may be provided in the intersection region 303 in order couple microwave power into each of the circular portions 305_{A}, 305_{B}, and 305_{C}. As such, the plasma flux distribution can be spread even wider.

Referring now to FIG. 3D, a cross-sectional illustration of a portion of a microwave plasma source 300 is shown, in accordance with an additional embodiment. In an embodiment, the microwave plasma source 300 in FIG. 3D is similar to the microwave plasma source 300 in FIG. 3C, with the addition of a fourth circular portion 305_{D}. In an embodiment, the four circular portions 305_{A}, 305_{B}, 305_{C}, and 305_{D} may all partially overlap each other to form an intersection region 303. The intersection region 303 may be defined by the imaginary dashed lines that continue the circular shapes of each of the circular portions 305_{A}, 305_{B}, 305_{C}, and 305_{D}. Similar to the embodiments in FIGS. 3B and 3C, the hole 306 for the pin may be provided in the intersection region 303 in order couple microwave power into each of the circular portions 305_{A}, 305_{B}, 305_{C}, and 305_{D}. As such, the plasma flux distribution can be spread even wider.

In an embodiment, any of the dielectric resonators 310 described with respect to FIGS. 3A-3D may be used in conjunction with a microwave plasma source similar to microwave plasma source 200 described in greater detail above with respect to FIGS. 2B and 2C. That is, a wide area plasma may be produced with an improved degree of plasma flux uniformity through the use of fewer dielectric resonators 310. As such, the benefits from using dielectric resonators 210 described above may also apply to the use of dielectric resonators 310 similar to those described with respect to FIGS. 3A-3D.

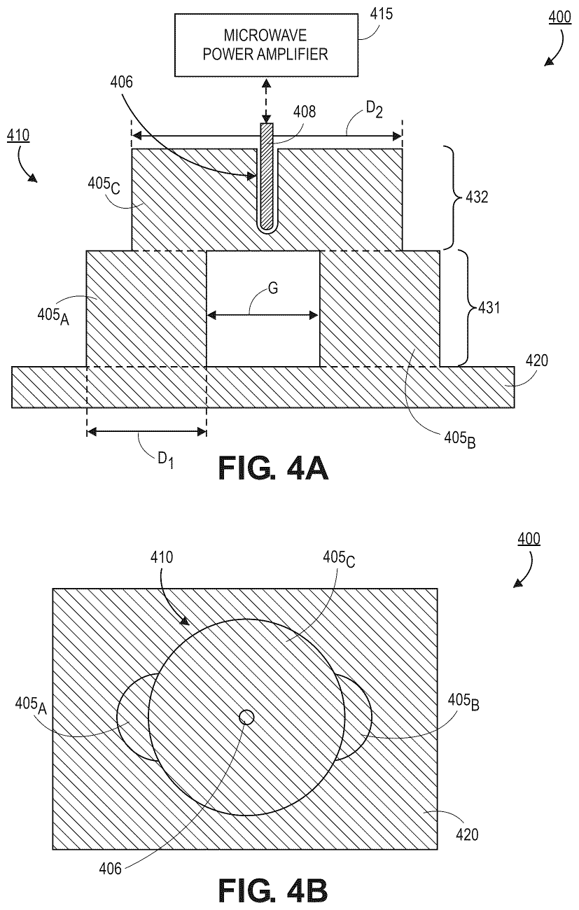

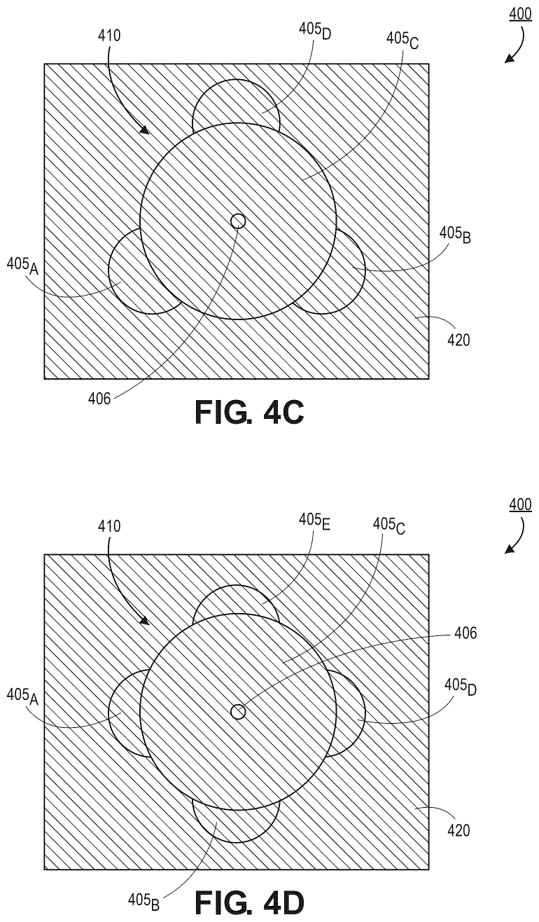

Referring now to FIGS. 4A-4D, a series of illustrations depicting a microwave plasma source 400 with dielectric resonators 410 with a first layer with a plurality of dielectric cavities and a second layer with a dielectric cavity that overlaps a portion of each of the underlying plurality of dielectric cavities is shown, in accordance with an embodiment.

Referring now to FIG. 4A, a cross-sectional illustration of a portion of a microwave plasma source 400 is shown, in accordance with an embodiment. In an embodiment, the microwave plasma source 400 may comprise a dielectric plate 420 and a dielectric resonator 410 coupled to the dielectric plate 420. In the illustrated embodiment, the dielectric resonator 410 and the dielectric plate 420 are a monolithic structure. Though, in other embodiments, the dielectric plate 420 and the dielectric resonator 410 may comprise discrete components. In an embodiment, the dielectric resonator 410 and the dielectric plate 420 may comprise any suitable dielectric material. For example, the dielectric resonator 410 and the dielectric plate 420 may comprise alumina or the like.

In an embodiment, the dielectric resonator 410 may comprise a plurality of dielectric cavities 405 arranged in a stack with at least two layers (e.g., a first layer 431 and a second layer 432). In an embodiment, each of the dielectric cavities 405 may be sized in order to provide a resonant cavity based on the frequency of the microwave power and the dielectric constant of the dielectric cavities 405. While not shown, an electrically conductive housing or shielding may be provided along sidewalls of the dielectric cavities 405.

In an embodiment, the dielectric resonator 410 may also comprise a hole 406 that passes into the third dielectric cavity 405_{C} in the second layer 432 that is provided over a first dielectric cavity 405_{A} and a second dielectric cavity 405_{B} that are located in the first layer 431. In an embodiment, an electrically conductive pin 408 may be inserted into the hole 406. In an embodiment, the hole 406 and pin 408 may be similar in construction, geometry, and/or orientation to any of the holes and/or pins described in greater detail herein. In a particular embodiment, the hole 406 may be positioned over a gap G between the first dielectric cavity 405_{A} and the second dielectric cavity 405_{B}. Though, the hole 406 may be positioned anywhere along a surface of the third dielectric cavity 405_{C}.

In an embodiment, the pin 408 may be electrically coupled to a microwave power amplifier 415. The microwave power amplifier 415 and any intervening components and/or coupling structures (e.g., waveguides, coaxial cables, etc.) may be similar to any of those described in greater detail herein.

In an embodiment, microwave power from the microwave power amplifier is propagated to the pin 408. The dielectric cavities 405_{A}, 405_{B}, and 405_{C} of the dielectric resonator 410 allow for the microwave power to be coupled into the dielectric material and propagate into the dielectric plate 420. The bottom surface of the dielectric plate 420 may be within a vacuum chamber that can support a plasma that is ignited and sustained by the microwave power.

In an embodiment, the first dielectric cavity 405_{A} and the second dielectric cavity 405_{B} may be adjacent to each other and spaced apart from each other by the gap G. The third dielectric cavity 405_{C} may span the gap G and overlap a portion of a footprint of each of the first dielectric cavity 405_{A} and the second dielectric cavity 405_{B}. Though, in some embodiments, the first dielectric cavity 405_{A} and the second dielectric cavity 405_{B} may directly contact each other, or even intersect each other (e.g., similar to the dielectric resonator 310 described with respect to FIG. 3B). In an embodiment, the dielectric cavities 405_{A}, 405_{B}, and 405_{C} may form a monolithic structure. That is the dashed line between the first dielectric cavity 405_{A} and the third dielectric cavity 405_{C} and/or the dashed line between the second dielectric cavity 405_{B} and the third dielectric cavity 405_{C} may not be indicative of an actual seam that is present in the dielectric resonator 410. Though, in some embodiments, one or more of the dielectric cavities 405_{A}, 405_{B}, and/or 405_{C} may be discrete structures.

In an embodiment, the first dielectric cavity 405_{A} and the second dielectric cavity 405_{B} may have a first diameter D₁, and the third dielectric cavity 405_{C} may have a second diameter D₂. In some embodiments, the first diameter Dᵢ is different than the second diameter D₂. In yet another embodiment, the first diameter D₁ may be the same as the second diameter D₂.

In an embodiment, such a stacked dielectric resonator 410 structure may allow for a power splitting process. This allows for a single microwave power input to be split into a plurality of underlying dielectric cavities 405. As such, the plasma flux density may be spread while reducing a total number of microwave power generation channels within the system.

Referring now to FIG. 4B, a plan view illustration of a portion of the microwave plasma source 400 is shown, in accordance with an embodiment. As shown, the microwave plasma source 400 may comprise a dielectric plate 420 with a dielectric resonator 410 provided over the dielectric plate 420. The dielectric resonator 410 may be similar to the dielectric resonator 410 described in FIG. 4A. As shown, the dielectric resonator 410 may comprise a first dielectric cavity 405_{A} and a second dielectric cavity 405_{B}. In an embodiment, the third dielectric cavity 405_{C} overlaps a portion of the first dielectric cavity 405_{A} and a portion of the second dielectric cavity 405_{B}. The third dielectric cavity 405_{C} may be centered between the first dielectric cavity 405_{A} and the second cavity 405_{B} in some embodiments.

As shown in FIG. 4B, the first dielectric cavity 405_{A}, the second dielectric cavity 405_{B}, and the third dielectric cavity 405_{C} may be circular so that they have cylindrical shapes. Though, in other embodiments one or more of the dielectric cavities 405_{A}, 405_{B}, and/or 405_{B} may have conical or frustoconical shapes similar to dielectric pucks 205 described in greater detail herein.

Referring now to FIG. 4C, a cross-sectional illustration of a portion of a microwave plasma source 400 is shown, in accordance with an additional embodiment. In an embodiment, the microwave plasma source 400 in FIG. 4C is similar to the microwave plasma source 400 in FIG. 4B, with the addition of a fourth dielectric cavity 405_{D} that is provided in the first layer 431 (below the third dielectric cavity 405_{C}). In an embodiment, the three dielectric cavities 405_{A}, 405_{B}, and 405_{D} may all be partially overlapped by the overlying third dielectric cavity 405_{C}. Similar to the embodiment in FIG. 4B, the hole 406 for the pin may be provided in the gap between each of the dielectric cavities 405_{A}, 405_{B}, and 405_{D} in the first layer 431 in order couple microwave power into each of the dielectric cavities 405_{A}, 405_{B}, and 405_{D}. As such, the plasma flux distribution can be spread even wider.

Referring now to FIG. 4D, a cross-sectional illustration of a portion of a microwave plasma source 400 is shown, in accordance with an additional embodiment. In an embodiment, the microwave plasma source 400 in FIG. 4D is similar to the microwave plasma source 400 in FIG. 4C, with the addition of a fifth dielectric cavity 405_{E} that is provided in the first layer 431 (below the third dielectric cavity 405_{C}). In an embodiment, the four dielectric cavities 405_{A}, 405_{B}, 405_{D}, and 405_{E} may all be partially overlapped by the overlying third dielectric cavity 405_{C}. Similar to the embodiment in FIG. 4B, the hole 406 for the pin May be provided in the gap between each of the dielectric cavities 405_{A}, 4058, 405_{D}, and 405_{E} in the first layer 431 in order couple microwave power into each of the dielectric cavities 405_{A}, 405_{B}, 405_{D}, and 405_{E}. As such, the plasma flux distribution can be spread even wider.

In an embodiment, any of the dielectric resonators 410 described with respect to FIGS. 4A-4D may be used in conjunction with a microwave plasma source similar to microwave plasma source 200 described in greater detail above with respect to FIGS. 2B and 2C. That is, a wide area plasma may be produced with an improved degree of plasma flux uniformity through the use of fewer dielectric resonators 410. As such, the benefits from using dielectric resonators 410 described above may also apply to the use of dielectric resonators 410 similar to those described with respect to FIGS. 4A-4D.

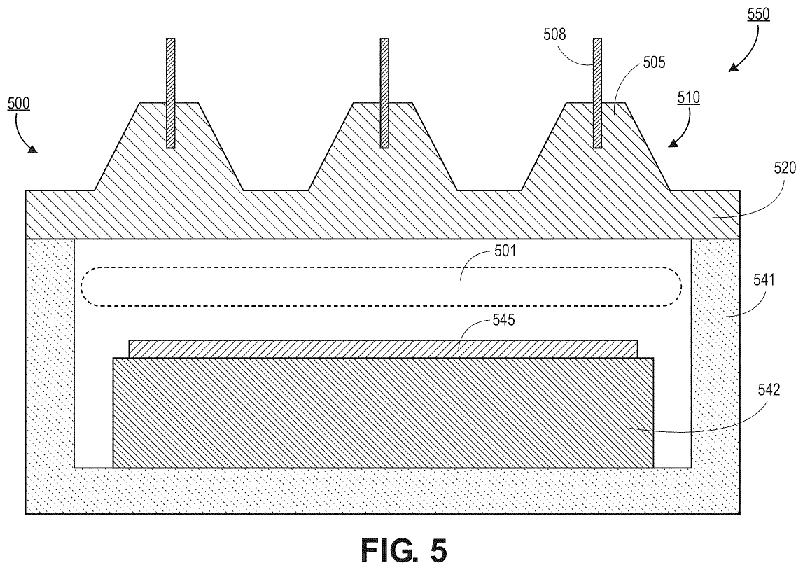

Referring now to FIG. 5, a cross-sectional illustration of a processing tool 550 for processing substrates 545 with a plasma process is shown, in accordance with an embodiment. In an embodiment, the processing tool 550 may be a microwave plasma chamber suitable for etching, deposition, plasma treatments, and/or the like. The processing tool 550 may comprise a chamber 541, such as a chamber 541 suitable for supporting a vacuum or the like. Exhaust lines, pumps, slit valves, gas inputs, and/or the like are omitted from the chamber 541 for simplicity. In an embodiment, a pedestal 542, heater, chuck, stage, or the like may be provided within the chamber 541 for supporting a substrate 545. In an embodiment, the pedestal 542 may be configured to rotate. The substrate 545 may be a semiconductor wafer of any form factor (e.g., 300 mm, etc.) or any other type of substrate suitable for processing with a plasma process.

In an embodiment, a microwave plasma source 500 may be provided as a lid or a part of a lid that seals the chamber 541. In an embodiment, the microwave plasma source 500 may comprise a dielectric plate 520 with a plurality of dielectric resonators 510 arranged in a pattern across the dielectric plate 520. While three dielectric resonators 510 are shown in FIG. 5, it is to be appreciated that the microwave plasma source 500 may comprise any number of dielectric resonators 510.

In an embodiment, the dielectric resonators 510 may be substantially similar to any of the dielectric resonators described in greater detail herein. For example, FIG. 5 illustrates the dielectric resonators 510 as comprising a dielectric puck 505 with sloped sidewalls (similar to dielectric resonators 210 in FIG. 2A). Though, dielectric resonators 510 may also be similar to dielectric resonators 310, dielectric resonators 410, or any combination of dielectric resonators described herein. In an embodiment, the dielectric resonators 510 may each include an electrically conductive pin 508 inserted into the dielectric puck 505. Each of the dielectric resonators 510 may be electrically coupled to different microwave power amplifiers (not shown) to allow for independent control of each dielectric resonator 510.

Similar to embodiments described herein, the architecture of the dielectric resonators 510 provides improved plasma flux spreading. This allows for a high degree of plasma flux uniformity across the diameter of the substrate 545. For example, the degree of uniformity of the plasma flux across the diameter of the substrate 545 may be approximately 90% or higher, approximately 95% or higher, approximately 97% or higher, or approximately 99% or higher. Embodiments may also allow for a reduction in a total number of dielectric resonators 510 compared to the use of cylindrical dielectric resonators. This allows for a reduction in the cost of the processing tool, and the control of plasma 501 is simplified. Accordingly, the processing tool 550 may be useable over a wider processing window, which can increase the versatility and value of the processing tool 550.

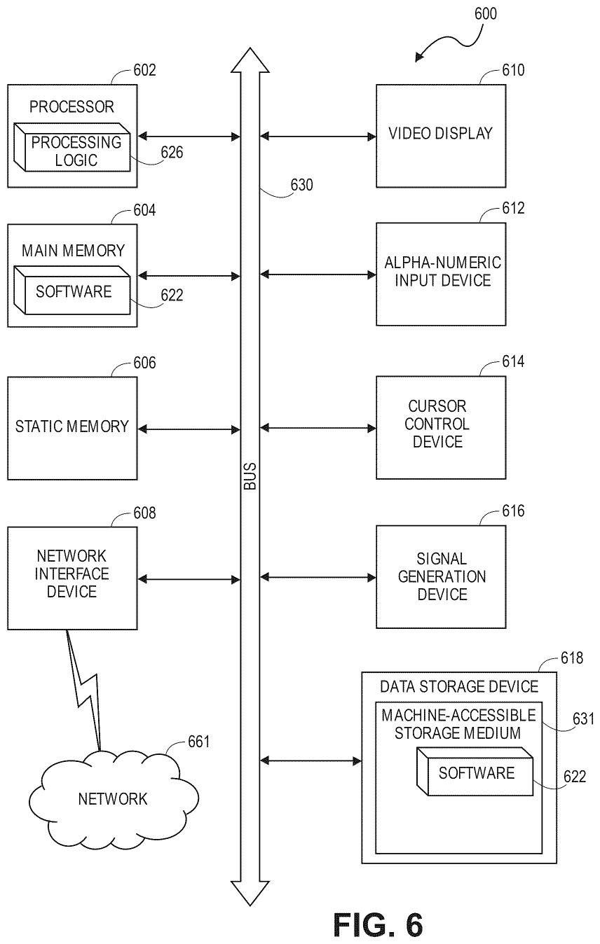

Referring now to FIG. 6, a block diagram of an exemplary computer system 600 of a processing tool is illustrated in accordance with an embodiment. In an embodiment, computer system 600 is coupled to and controls processing in the processing tool. Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 631 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 661 via the system network interface device 608. In an embodiment, the network interface device 608 may operate using RF coupling, optical coupling, acoustic coupling, or inductive coupling.

While the machine-accessible storage medium

631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An apparatus, comprising:
a plate, wherein the plate comprises a first dielectric material; and
a resonator coupled to the plate, wherein the resonator comprises a second dielectric material, wherein the resonator has a cross-sectional shape with a first end with a first width and a second end with a second width that is smaller than the first width, and wherein the first end faces the plate.

2. The apparatus of claim 1, further comprising:
a hole into the second end of the resonator.

3. The apparatus of claim 1, wherein the resonator has a frustoconical shape.

4. The apparatus of claim 3, wherein a slope of a sidewall of the frustoconical shape is between 30° and 60°.

5. The apparatus of claim 1, wherein the second width is 80% of the first width or smaller.

6. The apparatus of claim 1, wherein the first dielectric material and the second dielectric material are the same material, and wherein the plate and the resonator are a monolithic structure.

7. The apparatus of claim 1, further comprising:
a plurality of resonators coupled to the plate, wherein each of the plurality of resonators comprise a frustoconical shape.

8. An apparatus, comprising:
a plate, wherein the plate comprises a first dielectric material; and
a resonator coupled to the plate, wherein the resonator comprises a second dielectric material, and wherein the resonator comprises:
a first circular portion; and
a second circular portion that intersects the first circular portion.

9. The apparatus of claim 8, wherein the first circular portion and the second circular portion comprise a monolithic structure.

10. The apparatus of claim 8, further comprising:
a hole into the resonator, wherein the hole is provided in an area of the resonator where the second circular portion intersects the first circular portion.

11. The apparatus of claim 8, wherein the first circular portion has a first diameter and the second circular portion comprise a second diameter that is the same as the first diameter.

12. The apparatus of claim 8, further comprising:
a third circular portion that intersects the first circular portion and the second circular portion.

13. The apparatus of claim 12, further comprising:
a fourth circular portion that intersects the first circular portion, the second circular portion, and the third circular portion.

14. The apparatus of claim 8, wherein the resonator and the plate are a monolithic structure.

15. An apparatus, comprising:
a plate, wherein the plate comprises a first dielectric material; and
a resonator coupled to the plate, wherein the resonator comprises a second dielectric material, and wherein the resonator comprises:
a first layer on the plate, wherein the first layer comprises:
a first dielectric cavity; and
a second dielectric cavity adjacent to the second dielectric cavity; and
a second layer on the first layer, wherein the second layer comprises a third dielectric cavity that overlaps at least a portion of the first dielectric cavity and at least a portion of the second dielectric cavity.

16. The apparatus of claim 15, wherein the first dielectric cavity and the second dielectric cavity are cylinders with a first diameter, and wherein the third dielectric cavity is a cylinder with a second diameter, wherein the second diameter is greater than the first diameter.

17. The apparatus of claim 15, wherein the first layer further comprises:
a fourth dielectric cavity, and wherein the third dielectric cavity overlaps at least a portion of the fourth dielectric cavity.

18. The apparatus of claim 17, wherein the first layer further comprises:
a fifth dielectric cavity, wherein the third dielectric cavity overlaps at least a portion of the fifth dielectric cavity.

19. The apparatus of claim 15, wherein the first dielectric cavity, the second dielectric cavity, and the third dielectric cavity are a monolithic structure.

20. The apparatus of claim 15, further comprising:
a hole into the third dielectric cavity, wherein the hole is outside of a first footprint of the first dielectric cavity and outside of a second footprint of the second dielectric cavity.
